(19) United States
(12) Patent Application Publication
(10) Pub. No.: US 2026/0307532 A1
(43) Pub. Date: Oct. 8, 2026

(54) INTERMEDIARY CALIBRATION DEVICE USING ELECTRIC VEHICLE BATTERY AS ELECTRICAL LOAD

(71) Applicant: Fluke Corporation, Everett, WA (US)

(72) Inventors: Theodore J. Brillhart, Seattle, WA (US); James J. Withey, Berkshire (GB)

(21) Appl. No.: 19/172,290

(22) Filed: Apr. 7, 2025

(51) Int. Cl. B60L 58/12; B60L 3/12; G01R 31/36; H02J 7/82

(52) U.S. Cl. CPC B60L 58/12; B60L 3/12; G01R 31/3648; H02J 7/82; B60L 2250/16

(57) ABSTRACT

An intermediary calibration device is usable to calibrate a power source such as an electric vehicle supply equipment (“EVSE”) using a battery such as an electric vehicle (“EV”) battery as an electrical load. The intermediary calibration device determines a target electrical output to be supplied by the EVSE to the EV battery. In various embodiments, the intermediary calibration device notifies a battery management system associated with the EV battery that the EVSE is capable of providing the target electrical output. The intermediary calibration device receives a request from the battery management system for the EVSE to supply the target electrical output to the EV battery, and measures a value of the electrical output actually supplied by the EVSE to the EV battery. The EVSE is calibrated using at least the measured value of electrical output and a value of electrical output reported by the EVSE.

### BACKGROUND

### Technical Field

The present disclosure relates to calibration of power sources, such as electric vehicle supply equipment.

### Description of the Related Art

Many power sources such as electric vehicle supply equipment (i.e., “EVSE” or “EV chargers”) are calibrated to ensure power output by the power source meets certain parameters. For example, an electric vehicle (“EV”) charger is often calibrated to ensure it is accurately measuring and dispensing power at one or more power levels. Calibrating a power source involves connecting the power source to an electrical load and measuring output of the power source delivered to the electrical load using a high-accuracy measurement device. The measurement device measures power output of the EVSE at various power levels and compares the measured power output to the requested power output to determine whether the EVSE is accurately delivering power across a relevant operating range. In some cases, if warranted, corrective calibration actions are taken with respect to the EVSE to ensure that the EVSE accurately delivers the requested power.

### BRIEF SUMMARY

An intermediary calibration device is usable to help calibrate an electric vehicle supply equipment (“EVSE”) using an electric vehicle (“EV”) battery as an electrical load. In at least one embodiment, the intermediary calibration device determines a target power that the EVSE can supply to the EV battery and that the EV battery can receive. The intermediary calibration device may notify a battery management system associated with the EV battery that the EVSE can provide the target power. The intermediary calibration device requests the EVSE to supply the target power to the EV battery, and measures a value of the power supplied by the EVSE to the electric vehicle battery. The EVSE is calibrated using the target power and the measured value of the power supplied by the EVSE.

### BRIEF DESCRIPTION OF THE SEVERAL VIEWS OF THE DRAWINGS

Non-limiting and non-exhaustive embodiments are described with reference to the following drawings. In the drawings, like reference numerals refer to like parts throughout the various figures unless otherwise specified.

For better understanding, reference will be made to the following Detailed Description, which is to be read in association with the accompanying drawings.

FIG. 1 is a context diagram illustrating an environment in which an intermediary calibration device operates in some embodiments.

FIG. 2 illustrates an interface of an intermediary calibration device in some embodiments.

FIG. 3 is a context diagram illustrating a non-limiting example of a system that provides functionality for an intermediary calibration device in some embodiments.

FIG. 4 is a logical flow diagram illustrating a process for calibrating an electric vehicle supply equipment wherein an electric vehicle is used as an electrical load in some embodiments.

FIG. 5 is a logical flow diagram illustrating a process for determining one or more calibration points for an intermediary calibration device in some embodiments.

FIG. 6 illustrates examples of scenarios in which a calibration standard can or cannot be accommodated by a battery.

FIG. 7 is a system diagram that describes an implementation of a computing system for implementing embodiments described herein.

### DETAILED DESCRIPTION

Calibrating an electrical power source such as an EVSE typically involves comparing a reported power or energy output to a measured power or energy output of the EVSE, preferably at two or more calibration points. According to conventional techniques, power provided by the power source during calibration is directed to an electrical load such as a resistor where the power delivered is dissipated as heat. Often, to capture performance of the power source across its operating range, a first calibration point is near a low end of the power source’s power output, and a second calibration point is near a high end of the power source’s power output. In at least one non-limiting example, when an EVSE’s power output range is 1kW to 250kW, the first calibration point may be 5kW and the second calibration point may be 245kW. Because some EVSEs are configured to deliver power in excess of 250kW, calibration of EVSEs routinely involves dissipating significant power as heat at the electrical load.

To potentially dissipate 250kW or more at the electrical load while calibration is performed, the electrical load often includes significant thermal mass, active cooling, or both. Accordingly, conventional electrical loads for high-power calibration tend to be expensive, heavy, and inconvenient. Electrical loads used to calibrate EVSEs may weigh thousands of pounds and require a trailer or flatbed to haul. The inconvenience and expense of conventional calibration methods for EVSEs hinders installation and maintenance of EVSEs and adoption of electric vehicles.

EVs include high-capacity batteries capable of absorbing the high-power energy output of EVSEs. Thus, an EV battery can be used as an electrical load for calibration. Using an EV battery as the electrical load is more convenient and cost-effective, as the technician can drive the EV to the EVSE site without hauling a conventional electrical load. In conventional configurations, a measurement device is connected between the EV battery and the EVSE. Based on the energy intake capabilities of the EV battery, typically dictated by the EV battery’s state of charge, a battery management system (BMS) of the EV negotiates with the EVSE for a particular power output from the EVSE, such as 240 volts at 200 amps. The EVSE then delivers energy at this power level to the EV battery.

While the energy output of an EVSE to an EV battery can be measured during conventional operation, the usefulness of such measurements can be limited for calibrating the EVSE. Because a technician cannot control the energy output that the EV BMS requests from the EVSE, the technician can only calibrate the EVSE at the power level requested by the BMS. Power sources including EVSEs typically have different performance characteristics across a range of output power levels. Measuring the EVSE at only one power output (e.g., “single point calibration”) is often metrologically insufficient. Calibration at multiple power levels (e.g., “multi-point calibration”) is standard for calibrating most power sources. Thus, according to conventional techniques, an EV battery is not viewed as suitable for use as an electrical load for calibrating EVSEs.

In response to the disadvantages of conventional EVSE calibration techniques, the inventors have conceived of an intermediary calibration device that facilitates use of an electric vehicle battery as an electrical load for multi-point calibration of an EVSE.

In various embodiments, the intermediary calibration device is in communication with the EV and the EVSE and controls communications between the EV and the EVSE. Throughout the present disclosure, communication with the EV is generally regarded as communication with the BMS of the EV. Additionally, throughout the present disclosure, energy that is output by an EVSE is sometimes referred to or measured as a power output or power transfer by the EVSE.

The intermediary calibration device negotiates with the EVSE to output power according to a specific set of conditions (e.g., voltage and current) and either concurrently or in sequence negotiates with the EV to accept the power output of the EVSE at the negotiated set of conditions (or vice versa). The negotiation takes place through communication familiar to the EVSE and the EV, for example through communication protocols known or used by each of the EVSE and EV. The communication is such that the intermediary calibration device appears to the EVSE as the EV and independently the intermediary calibration device appears to the EV as the EVSE. Once the intermediary calibration device completes the negotiation with both the EVSE and the EV, the intermediary calibration device confirms the specific conditions for the desired charging of the EV and starts the power transfer. The intermediary calibration device or other circuitry measures the power output by the EVSE and at an appropriate time stops the power transfer. This sequence of negotiation and power transfer can be repeated almost immediately using different sets of conditions to obtain a multi-point calibration of the EVSE.

In various embodiments, the specific set of conditions used for a calibration operation will either be set by the user of the intermediary calibration device or chosen by the user from a list of predetermined conditions or present standards prior to negotiation with or configuration of the EVSE and EV. This enables performance of calibration operations for a multi-point calibration of the EVSE.

In some embodiments, the intermediary calibration device communicates to the EV a capability of the EVSE to deliver energy at a power level at which the EVSE is to be calibrated. To the EV, the communication by the intermediate calibration device appears to be received from the EVSE. For example, when the EVSE is to be calibrated at 240 volts and 30A, the intermediary calibration device represents to the EV that the EVSE is only capable of outputting power at 240 volts and 30A, regardless of the actual capability of the EVSE to output power at other power levels. The EV in turn requests charging at the apparent available power of 240 volts and 30A (assuming the state of charge of the EV battery allows the EV to be charged at that power level). This request is communicated from the EV to the intermediary calibration device. The intermediary calibration device in turn communicates to the EVSE a request to deliver energy to the EV at the requested power level. To calibrate the EVSE, the power that is output from the EVSE to the EV is measured and compared to the actual power output reported by the EVSE. At a subsequent step in the calibration, the intermediary calibration device communicates to the EV that the EVSE is capable of outputting energy at a different power level (i.e., at a different voltage and/or current) whereupon the EV requests charging at the new power level. This request is communicated by the intermediary calibration device to the EVSE, and the EVSE outputs energy to the EV at the requested power level. The energy output is measured and compared to the EVSE’s reported energy output to calibrate the EVSE. This enables multi-point calibration of EVSEs to be performed using an EV battery as an electrical load.

In other embodiments, the intermediary calibration device may begin the negotiation by communicating to the EVSE a requested power level for power delivery at which the EVSE is to be calibrated. To the EVSE, the request appears to be received from the EV. For example, when the desired calibration point is for energy to be delivered to the EV at a power level of 240V and 30A, the intermediary calibration device communicates to the EVSE a requested output power at 240V and 30A, even if the EV battery is capable of being charged at a higher power level, assuming of course that the state of charge of the EV battery allows the EV to be charged at the requested power level. For calibration of the EVSE, the energy that is actually output from the EVSE to the EV is measured and compared to the energy output reported by EVSE. At a subsequent step in the multi-point calibration, the intermediary calibration device negotiates with the EV and EVSE to charge the EV at a different voltage and/or current whereupon the EVSE outputs energy to the EV at the new power level. The energy output by the EVSE is measured and compared to the EVSE’s reported energy output. In this manner, a multi-point calibration of the EVSE is performed.

While calibration of an EVSE using an EV battery as an electrical load is discussed as an example herein, the disclosure is not so limited. In various embodiments, techniques disclosed herein are used to calibrate any system for which calibration includes use of an electrical load. In various non-limiting examples, the intermediary calibration device is used to calibrate power generating equipment such as a solar module, wind turbine, hydroelectric power station, etc. In various embodiments, techniques disclosed herein are used to calibrate various energy delivery infrastructure such as power transmission or distribution lines, power transformers, power meters, etc.

Moreover, while use of an EV battery as an electrical load is discussed as a non-limiting example herein, in various embodiments any suitable battery may be used. In at least one non-limiting example, a large-scale battery storage system (e.g., a battery energy storage system) installed at a solar array is used as an electrical load for calibrating output of one or more components of the solar array. In some embodiments, the battery is a mobile battery storage unit.

In various embodiments, the electrical load is any energy storage system capable of receiving power at levels suitable for calibrating the power supply, such as a pumped hydroelectric storage system, a thermal energy storage system, a compressed air energy storage system, a flywheel energy storage system, etc.

Additionally, while examples herein discuss calibrating an output of a power source using a battery as an electrical load, the disclosure is not so limited. In various embodiments, the battery may supply power to the power source, which in turn supplies power to an electrical grid or other electrical load. This enables power provided by the power source (e.g., from the battery) to be calibrated. To illustrate, power from a residential photovoltaic (PV) installation may be stored in a battery of an electric vehicle connected to the PV installation via an EVSE, such as when power produced by the PV installation exceeds power use by the residence. The power can later be provided from the battery to the grid through the EVSE. To ensure accurate power metering from the battery to the grid via the EVSE, power output of the battery to the EVSE may be calibrated.

In various embodiments, power provided from the battery to the grid using the power source, power provided from the grid to the battery using the power source, or both, may be calibrated (e.g., the calibration may be “bidirectional”).

In various embodiments, calibration of the power source’s power provision from the battery to the grid (or other electrical load) is performed similar to calibration of the power source’s power provision from the grid (or other energy source) to the battery. In some embodiments, the intermediary calibration device negotiates with a battery management system of the battery to provide power from the battery to the power source according to a specific set of conditions (e.g., voltage and current). References herein to “battery” and “battery management system” may equally be considered more generally as reference to a “load” and “load management system” that regulates power flowing to (and possibly from) the load.

In some embodiments, the intermediary calibration device negotiates with the power source to confirm that the power source is capable of receiving the specified power from the battery (e.g., to provide power to a load, such as the grid). Once the intermediary calibration device completes negotiation between the battery and the power source, power is provided from the battery to the power source. The intermediary calibration device or other circuitry measures the power provided from the battery to the power source and at an appropriate time stops the power transfer. The process of negotiation, power transfer, and measuring can be repeated using different sets of conditions to obtain multi-point calibration of the battery’s provision of power to the power source.

While calibration of power provided from a battery is discussed as an example herein, the disclosure is not so limited. In various embodiments, techniques disclosed herein are used to calibrate provision of power from any system to another system, such as the grid. In various non-limiting examples, the intermediary calibration device is used to negotiate and calibrate power supplied by any power generating equipment such as a solar module, wind turbine, hydroelectric power station, etc. In various embodiments, techniques disclosed herein may be used to calibrate various energy delivery infrastructure such as power transmission or distribution lines, power transformers, power meters, etc.

As used herein, the term “calibration” refers to a procedure of standardizing performance of a device such as an electric vehicle supply equipment by determining a deviation of a measured performance of the device from a reported performance, which enables correction of the determined deviation.

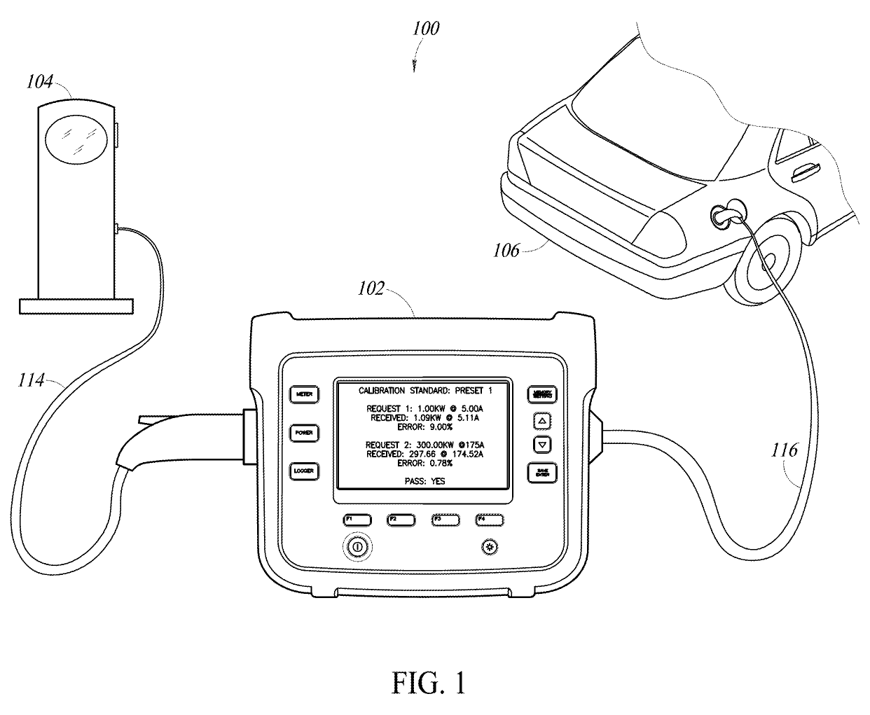

FIG. 1 is a context diagram illustrating an environment 100 in which an intermediary calibration device operates in some embodiments. Environment 100 includes intermediary calibration device 102, electric vehicle supply equipment ( “EVSE”) 104, and electric vehicle ( “EV”) 106.

Intermediary calibration device 102 is configured to control communication between EVSE 104 and EV 106 to cause EVSE 104 to provide energy to EV 106 at a desired power level, measure the provided energy, and calibrate the EVSE 104 based on a deviation of the measured energy from the energy delivery reported by the EVSE.

During conventional operation of EVSE 104, charging cable 114 is directly connected to EV 106. EVSE 104 communicates its charging capabilities such as a minimum or maximum voltage or current that can be provided, etc. to a battery management system (“BMS”) of the EV 106. The BMS determines a charging request for the EVSE based on a battery charge status, battery requirements, capabilities of the EVSE, or other conditions, etc. The BMS provides the charging request to the EVSE. The EVSE confirms that it can fulfill the charging request and provides energy at the requested power level to EV 106. The EV 106 confirms that the power provided by the EVSE is as requested. When the power provided by the EVSE is as requested, the EV completes a circuit to the battery and charging begins.

Accordingly, conventional operation of EVSE 104 and EV 106 is typically a highly orchestrated process, wherein the BMS of EV 106 determines a charging voltage and current to request from EVSE 104. As discussed herein, while the charging voltage and current provided by the EVSE in response to a request from the EV may be measured and compared to the reported voltage and current, this only enables calibration of the EVSE at a single calibration point determined by the EV BMS.

To enable multi-point calibration of EVSE 104 using the EV battery as an electrical load, an intermediary calibration device 102 as disclosed herein is connected to EVSE 104 using charging cable 114 and connected to EV 106 using charging cable 116. Intermediary calibration device 102 manages communication with EVSE 104 and EV 106. In various embodiments, intermediary calibration device 102 determines a calibration point (e.g., a selected current and voltage) at which to calibrate EVSE 104. Following negotiations with the EVSE 104 and EV 102, intermediary calibration device 102 controls communications with EVSE 104 and EV 102 to cause EVSE 104 to deliver energy at the selected current and voltage to EV 106. Intermediary calibration device 102 calibrates the EVSE 104 by measuring the actual energy delivered by the EVSE at the current and voltage provided to the EV and compares the actual energy delivered to the energy delivery reported by the EVSE 104. This process may be repeated to obtain different measures of EVSE 104’s performance at multiple calibration points.

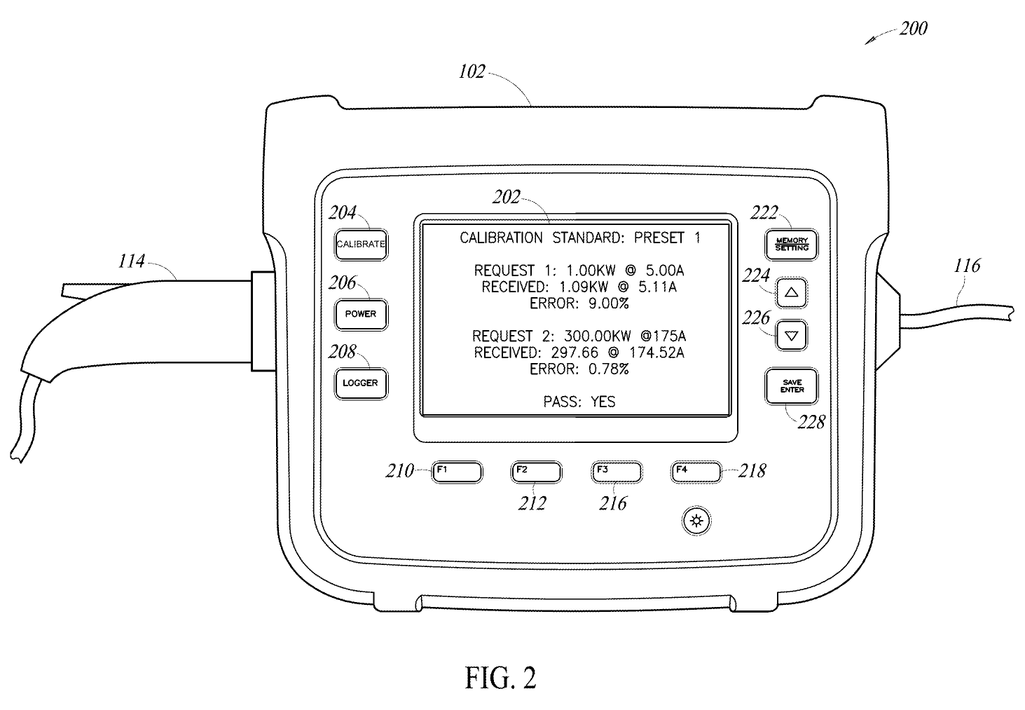

FIG. 2 illustrates an interface 200 of an intermediary calibration device 102 in some embodiments. In this example, the interface 200 includes display 202, calibrate button 204, power button 206, logger button 208, function buttons 210, 212, 216, and 218, memory button 222, up navigation button 224, down navigation button 226, and save or enter button 228.

Display 202 is configured to display user interface components or other information. In various embodiments, display 202 is a touch display or a non-touch display. As shown in FIG. 2, display 202 shows calibration data collected according to a calibration standard titled “Preset 1”. Preset 1 includes “Request 1” (i.e., “the first calibration point”) which specifies that the EVSE is requested to provide 1.00kW of power at 5.00A. The “Received” line indicates that, in response to a request based on the first calibration point, the EVSE actually provided 1.09kW at 5.11A as measured by intermediary calibration device 102 or other measurement circuitry. The “Error” line indicates that the power actually provided by the EVSE deviated from the first calibration point by 9.00%.

Preset 1 also includes “Request 2” (i.e., “the second calibration point”) which specifies that the EVSE is requested to provide 300.00kW of power at 175A. The “Received” line indicates that, in response to the request based on the second calibration point, the EVSE actually provided 297.66kW at 174.52A as measured by intermediary calibration device 102 or other measurement circuitry. The “Error” line indicates that the power actually provided by the EVSE deviated from the second calibration point by 0.78%.

While “Preset 1” is illustrated as including two calibration points, the disclosure is not so limited. In various embodiments, a preset includes any number of calibration points, such as 1, 2, 5, 10, etc. calibration points.

The “Pass” line indicates whether an error calculated based on the calibration points and measurements taken using intermediary calibration device 102 satisfies an error threshold specified by the Preset 1 calibration standard. As shown in FIG. 2, the “Yes” indicates that the measured output by the EVSE satisfies the error threshold. In various embodiments, a combination of a plurality of errors is compared to the error threshold.

In some embodiments, a combination of two or more errors includes averaging the two or more errors. In some embodiments, each error is compared to a same error threshold. For example, when the error threshold is 10%, the 9.0% error associated with the first calibration point and the 0.78% error associated with the second calibration point both satisfy the error threshold. Accordingly, the EVSE passes according to the preset 1 calibration standard. In various embodiments, the calibration standard specifies a number or proportion of passing measurements that indicate passing the calibration standard.

In various embodiments, a plurality of errors is compared to a corresponding plurality of error thresholds to determine whether the EVSE passes according to the calibration standard. In at least one non-limiting example, the first calibration point is associated with a first error threshold of 10% and the second calibration point is associated with a second error threshold of 1%. In the example shown on display 202, the measurements corresponding to the first calibration point and the second calibration point both satisfy their corresponding error thresholds, because 9.00% is less than 10% and 0.78% is less than 1%. Thus, the EVSE passes according to the preset 1 calibration standard.

In various embodiments, display 202 may exclude one or more of the display components shown in FIG. 2, or may include one or more additional display components, or both. In at least one non-limiting embodiment, display 202 indicates the calibration standard being used and whether the EVSE passes the calibration standard.

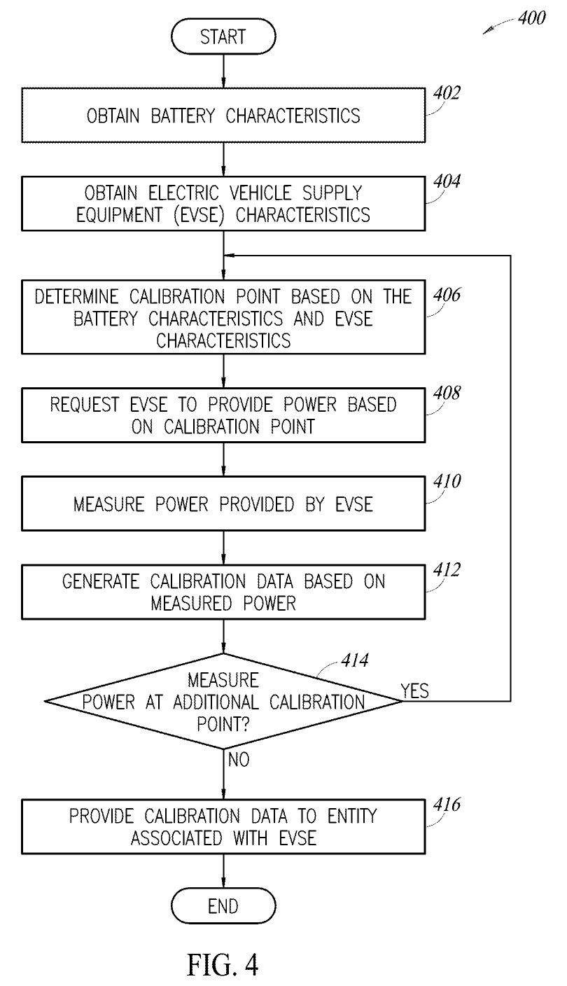

Calibrate button 204 is configured to begin a calibration process according to a selected calibration standard or calibration point. In at least one non-limiting example, in response to receiving a selection of the calibration button 204, intermediary calibration device 102 performs process 400 of FIG. 4.

Power button 206 enables intermediary calibration device 102 to be turned on or off. Logger button 208 enables automatic logging of calibration performed by intermediary calibration device 102. In some embodiments, automatic logging is toggled on or off using logger button 208.

In various embodiments, one or more of function buttons 210, 212, 216, and 218 are programmable buttons. In some embodiments, a user selects a calibration standard to correspond to a function button. Selection of the function button then initiates calibration using the corresponding calibration standard. In various embodiments, a functionality of the intermediary calibration device 102 is user selected to correspond to a function button.

In various embodiments, in response to receiving selection of memory/setting button 222, intermediary calibration device 102 displays a menu that includes one or more calibration standards or calibration points saved in memory. In some embodiments, the user selects a calibration standard for use in calibration. In some embodiments, the user selects a calibration standard to be edited.

In various embodiments, the user is permitted to edit some calibration standards but not other calibration standards. In at least one non-limiting example, the user is permitted to edit custom calibration standards configured by the user. In another non-limiting example, the user is permitted to edit locally saved calibration standards but not calibration standards obtained from another computing device such as a server. In some embodiments, the user is permitted to edit some elements of a calibration standard but not other elements. In at least one non-limiting example, the user is permitted to edit a name of the calibration standard, map the calibration standard to a control interface component, etc. but not edit a calibration point, error threshold, etc. associated with the calibration standard.

In some embodiments, in response to configuration or selection of a calibration point or calibration standard, the intermediary calibration device 102 indicates a maximum charge capacity of an EV battery at which the EV battery can serve as an electrical load for calibrating the EVSE according to the calibration point or calibration standard. In at least one non-limiting example where the calibration point is 150kW (e.g., 480v at 312.5A), the intermediary calibration device indicates a maximum charge capacity of the battery at which the battery can serve as an electrical load for the calibration point. In various embodiments, the maximum charge capacity is determined based on a charge curve of the EV battery.

Up navigation button 224 and down navigation button 226 are configured to enable user navigation of interfaces displayed using display 202, such as to select a calibration standard to be used from a menu including one or more calibration standards, to modify a value such as a current or voltage of a calibration point of a calibration standard, etc.

Save/enter button 228 is configured to enable selection of an item displayed using display 202 or saving of the item depending upon a context in which selection of save/enter button 228 is received. In at least one non-limiting example, when a menu including several options is displayed using display 202, selection of save/enter button 228 selects an item. When a value of a calibration point is being edited, selection of save/enter button 228 saves the value of the calibration point.

While various inputs are described as buttons for ease of discussion, in various embodiments, any user interaction functionality of intermediary calibration device 102 may be implemented using any control interface. In some embodiments, the control interface includes an external input device such as a mouse, keyboard, microphone, etc. In some embodiments, the control interface includes one of more physical control interface components such as a button, knob, switch, etc. In some embodiments, the control interface includes one or more digital control interface components such as icons displayed on display 202. In at least one non-limiting example, display 202 is a touchscreen, and functionality of one or more of the buttons is provided via a graphical user interface displayed using display 202.

In various embodiments, intermediary calibration device 102 includes one or more ports configured to accept different types of plugs of EV charging cable 114 from EVSE 104 such as an SAE J1772 plug (i.e., a “type 1” connector), a Mennekes plug (i.e., a “type 2” plug), a Combined Charging System Standard (i.e., “CCS”) 1 or 2 plug, a North American Charging Standard (i.e., “NACS” ) plug, a Charge de Move (i.e., “CHAdeMO”) plug, a Guobiao Standard (i.e., “GB/T”) plug, etc. In some embodiments, intermediary calibration device 102 includes a plurality of ports configured to accept a corresponding plurality of plugs. In at least one non-limiting example, intermediary calibration device 102 includes a NACS port and a CCS port. In some embodiments, intermediary calibration device 102 includes a modular port into which various port adapters can be installed, enabling intermediary calibration device 102 to be used to calibrate EVSEs having plugs of various standards.

In various embodiments, charging cable 116 is similar to charging cable 114. In some embodiments, intermediary calibration device 102 includes a modular port into which charging cables 116 according to various standards can be installed.

In various embodiments, intermediary calibration device 102 uses any vehicle-to-grid communication protocol such as ISO 15118, IEC 61851-1, CHAdeMO, CharIN, Open Charge Point Protocol (i.e., “OCPP”), GB/T, a proprietary communication protocol, etc. to communicate with EVSE 104 and EV 106. In some embodiments, the communication protocol is unidirectional. In some embodiments, the communication protocol is bidirectional.

In various embodiments, intermediary calibration device 102 is configured to automatically determine a communication protocol to be used to communicate with EVSE 104 and EV 106. In some embodiments, intermediary calibration device 102 determines the communication protocol based on a message sent by EVSE 104 or EV 106. In some embodiments where intermediary calibration device 102 includes a modular port, intermediary calibration device 102 determines a communication protocol to be used based on an installed modular port, such as using a near-field communication device of the installed modular port.

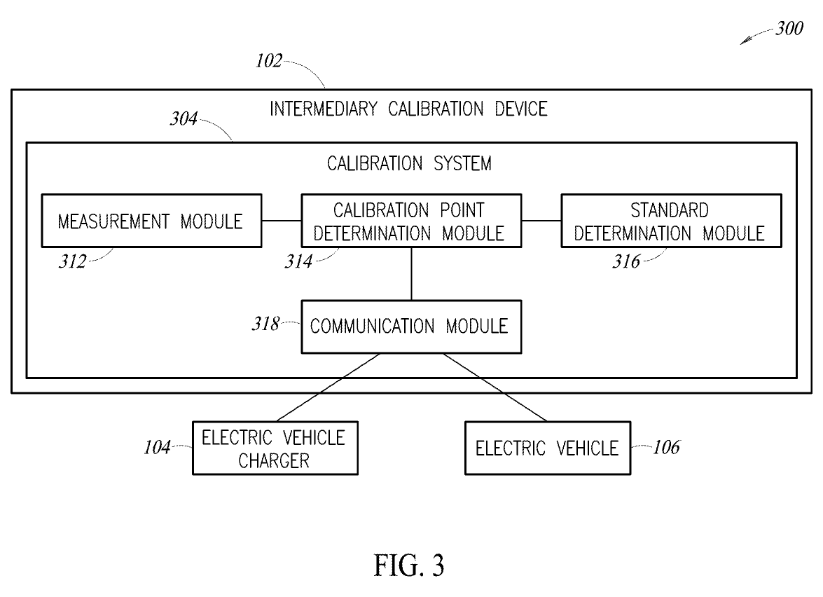

FIG. 3 is a context diagram illustrating a non-limiting example of a system 300 that provides functionality for an intermediary calibration device in some embodiments. System 300 includes intermediary calibration device 102, electric vehicle charger (EVSE) 104, and electric vehicle (EV) 106. Intermediary calibration device 102 includes calibration system 304, which is configured to perform calibration of EVSE 104 using a battery of EV 106 as an electrical load. Calibration system 304 includes measurement module 312, calibration point determination module 314, calibration standard determination module 316, and communication module 318.

Measurement module 312 is configured to measure energy or power provided by EVSE 104 to EV 106 via the intermediary calibration device 102. In some embodiments, measurement module 312 is configured to measure energy or power provided by EV 106 to EVSE 104 (e.g., bi-directional energy or power delivery). In some embodiments, measurement module 312 compares measurements of energy or power delivered by EVSE 104 to energy or power reported by EVSE 104 (or vice-versa) according to one or more calibration points determined using the calibration point determination module 314.

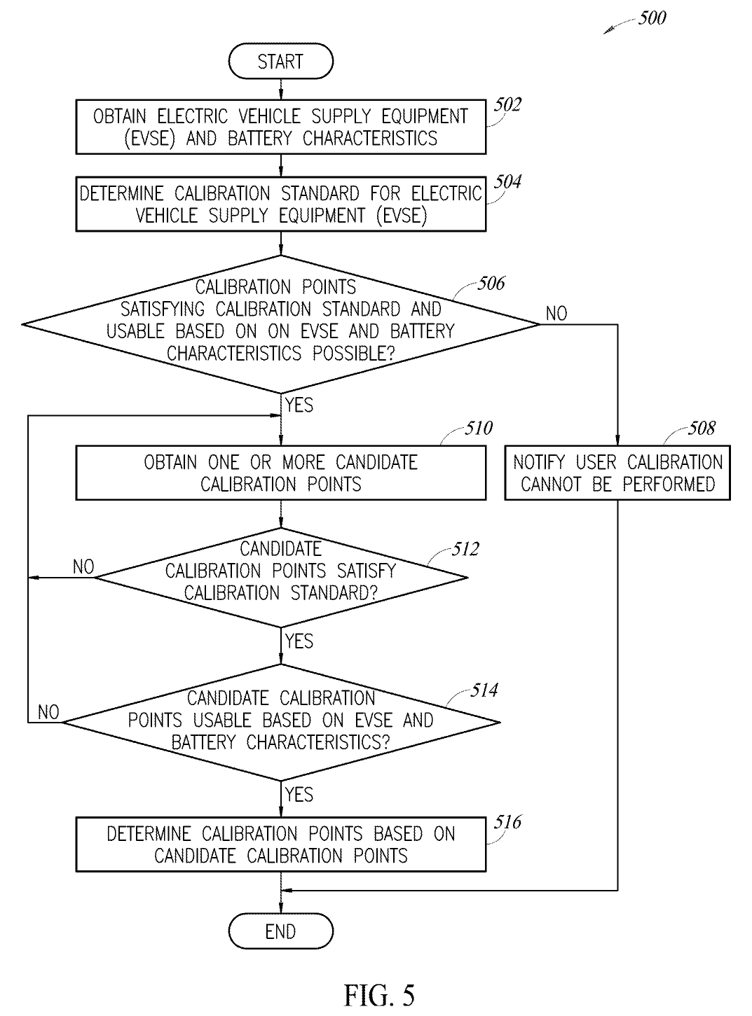

Calibration point determination module 314 is configured to determine one or more calibration points at which the intermediary calibration device is to calibrate EVSE 104. In various embodiments, calibration point determination module 314 employs embodiments of process 500 of FIG. 5 to determine the one or more calibration points. In some embodiments, calibration point determination module 314 determines the one or more calibration points based on a calibration standard determined by standard determination module 316.

Standard determination module 316 is configured to determine a calibration standard to be used to calibrate EVSE 104. In various embodiments, the calibration standard includes one or more power ranges at which EVSE 104 is to be calibrated, one or more specified calibration points at which EVSE 104 is to be calibrated, one or more error thresholds that correspond to one or more calibration points or calibration ranges, one or more entities to which calibration results for the calibration standard are to be automatically provided, etc. In at least one non-limiting example, a calibration standard specifies that EVSE 104 is to be calibrated at a first calibration point below 10% of its maximum power output and a second calibration point above 90% of its maximum power output, and that the EVSE passes the calibration if an average calibration error is less than 1%.

In various embodiments, standard determination module 316 determines the calibration standard based on a geographical location of EVSE 104 or intermediary calibration device 102, or a jurisdiction in which EVSE 104 operates. For example, various jurisdictions such as states, municipalities, or countries, may set different calibration standards for EVSE 104. Accordingly, in some embodiments, standard determination module 316 determines whether a calibration standard is available for a relevant jurisdiction, retrieving the calibration standard if it is available.

In some embodiments, standard determination module 316 determines the calibration standard based on an entity associated with EVSE 104 such as a manufacturer, owner, lessee, etc. of EVSE 104. For example, an EVSE owner may provide a calibration standard to be used to calibrate EVSE 104. Accordingly, in some embodiments, standard determination module determines whether an entity associated with has provided a calibration standard to be used, retrieving the calibration standard if it is available.

Communication module 318 is configured to enable communication between intermediary calibration device 102 and EVSE 104, EV 106, or another computing device. In some embodiments, communication module 318 includes one or more wireless connections, wired connections, or any combination thereof. In various embodiments, communication module 318 is configured to selectively enable or disable direct communication between EVSE 104 and EV 106.

FIG. 4 is a logical flow diagram illustrating a process 400 for calibrating an electric vehicle supply equipment wherein an electric vehicle is used as an electrical load in some embodiments. In various embodiments, process 400 is implemented using intermediary calibration device 102 of FIG. 1.

Process 400 begins at block 402, where battery characteristics are obtained. In various embodiments, the battery characteristics include one or more of: a maximum capacity of the battery, a current charge level of the battery, a maximum, minimum, or preferred charging rate of the battery, a level of wear of the battery, a temperature of the battery, etc. In some embodiments, one or more of the battery characteristics are obtained from a battery management system (“BMS”) of an electric vehicle by querying the BMS. In some embodiments, one or more of the battery characteristics are obtained based on a charge request directed to the EVSE from the BMS. In one non-limiting example, the charge request received from the BMS specifies a charging current for the battery at its present charge capacity. As discussed herein, the BMS will typically request charging at a maximum power that can be accommodated by the battery at its present charge capacity. Accordingly, in some embodiments, a power specified in the charge request is presumed to be a maximum power at which the battery can be charged at its present charge capacity.

In some embodiments, one or more of the battery characteristics are obtained from a database. In at least one non-limiting example, charging curve data or other battery characteristics are obtained from the database. After block 402, process 400 continues to block 404.

At block 404, electric vehicle supply equipment (EVSE) characteristics are obtained. In various embodiments, the EVSE characteristics include one or more of: a minimum output voltage, a maximum output voltage, a minimum output current, a maximum output current, etc. In some embodiments, the EVSE characteristics include a geographic location of the EVSE, a jurisdiction regulating the EVSE, an entity associated with the EVSE, a calibration standard associated with the EVSE, etc.

In some embodiments, one or more of the EVSE characteristics are obtained from the EVSE. In some embodiments, one or more of the EVSE characteristics are obtained from a database.

In various embodiments, the one or more EVSE characteristics are obtained based on a message transmitted by the EVSE directed to the EV BMS. As discussed herein, in conventional charging between the EVSE and the EV battery, the EVSE provides the EV BMS with its capabilities as part of initiating charging. In some embodiments, the intermediary calibration device intercepts this message such that the EV BMS does not receive the message. In some embodiments, the intermediary calibration device saves a copy of the message or a portion thereof to obtain the one or more EVSE characteristics. After block 404, process 400 continues to block 406.

At block 406, a calibration point is determined based on the battery characteristics and the EVSE capabilities. In various embodiments, block 406 employs embodiments of process 500 of FIG. 5 to determine the calibration point.

In some embodiments, the calibration point is based on a charging request received from the EV BMS. In some embodiments, the calibration point is determined based on a minimum power that can be provided by the EVSE.

In some embodiments, the calibration point is determined based on a saved calibration point, such as a calibration point saved in memory of the intermediary calibration device. In some embodiments, the saved calibration point is based on user input received by the intermediary calibration device. In some embodiments, the saved calibration point is received from another computing device such as a server. After block 406, process 400 continues to block 408.

At block 408, the EVSE is requested to provide power based on the calibration point. In some embodiments, the EVSE is requested to provide a selected voltage and a selected current of the calibration point.

In various embodiments, intermediary calibration device 102 causes the EV BMS to issue a request for power based on the calibration point. As discussed herein, as part of initiating charging, the EVSE typically provides information to a connected EV regarding capabilities of the EVSE such as a maximum deliverable current. When the EVSE communicates to the EV BMS a maximum power that the EVSE can provide, the EV BMS will typically negotiate to charge at the maximum power, even if it is less than a maximum power at which the EV battery can be charged. By inserting intermediary calibration device 102 into the communication path, the EV BMS can be “tricked” into negotiating charging at a specified calibration point by representing the specified calibration point to the EV BMS as a maximum power output of EVSE. For example, if the EV BMS would normally request the battery to be charged at 50 kW but the EV BMS receives an indication that the EVSE is only capable of charging at 30 kW, the EV BMS will typically negotiate charging at 30 kW. The EVSE thereafter outputs energy to the EV at a reported power level based on the negotiated (requested) power. After block 408, process 400 continues to block 410.

At block 410, power (or energy as the case may be) provided by the EVSE is measured. In various embodiments, a current, voltage, or both, of the EVSE’s actual power (or energy) output is measured. After block 410, process 400 continues to block 412. Again, in FIG. 4 and throughout this disclosure, references to measurement and calibration of energy output by an EVSE may be considered the same or using similar processes as for measurement and calibration of power output by the EVSE. In other words, in various embodiments references to power herein may appropriately be replaced with references to energy.

At block 412, calibration data is generated based on the measured power. In various embodiments, the calibration data indicates a difference between the power delivery reported by the EVSE (based on the calibration point) and the power actually provided by the EVSE. In some embodiments, the calibration data includes a percent error of the power provided as compared to the power reported. In some embodiments the calibration data includes a binary determination of whether a difference between the power provided and the power reported satisfies a difference threshold. In at least one non-limiting example, when the difference between the provided power and the reported power is 5% and the difference threshold is 10%, the calibration data reflects that the difference between the provided power and the reported power satisfies the difference threshold. After block 412, process 400 continues to decision block 414.

At decision block 414, a determination is made whether to measure power provided by the EVSE at an additional calibration point. If yes, process 400 proceeds to block 406. If no, process 400 proceeds to block 416. In some embodiments wherein power is to be measured at an additional calibration point, the additional calibration point is determined at block 406 based on the calibration point previously determined at block 406. In some embodiments, the additional calibration point is selected to maximize a distance between the calibration point and the additional calibration point or such that a difference between the calibration point and the additional calibration point exceeds a difference threshold. In at least one non-limiting example, when the calibration point is 1 kW, the additional calibration point is a maximum power or near a maximum power at which the EV battery can be charged. In some embodiments, the additional calibration point is determined in conjunction with the first calibration point at the first instance of block 406 and is retrieved for use at a subsequent instance of block 406.

At block 416, calibration data is provided to an entity associated with the EVSE. In some embodiments, the entity associated with the EVSE is a regulatory entity, such as an entity that regulates calibration of the EVSE. In some embodiments, the entity associated with the EVSE is a technician making the measurement. In some embodiments, the calibration data is provided to a plurality of entities associated with the EVSE. The calibration data may be used to determine and apply corrective action to the EVSE to reduce or eliminate the difference between the power actually provided and the power reported by the EVSE. After block 416, process 400 ends.

While process 400 is described in terms of calibrating the EVSE using the EV as an electrical load, the disclosure is not so limited. In various embodiments, calibration is performed by measuring power provided from a battery to another electrical load, such as an electrical grid through the EVSE. Thus, in some embodiments, calibration may be based on providing power to the battery and based on receiving power from the battery (i.e. “bidirectional power delivery”).

The blocks shown in FIG. 4 and in each of the flow diagrams discussed below may be altered in a variety of ways. For example, the order of the blocks may be rearranged; some blocks may be performed in parallel; shown blocks may be omitted or other blocks may be included; a shown block may be divided into sub-blocks or multiple shown blocks may be combined into a single block, etc.

FIG. 5 is a logical flow diagram illustrating a process 500 for determining one or more calibration points in some embodiments. In various embodiments, block 406 of process 400 employs embodiments of process 500 to determine a calibration point based on battery characteristics and EVSE characteristics.

Process 500 begins at block 502 where EVSE and battery characteristics are obtained. In various embodiments, the EVSE and battery characteristics are similar to those described with respect to blocks 404 and 402 of FIG. 4, respectively. After block 502, process 500 continues to block 504.

At block 504, a calibration standard for the EVSE is determined. In various embodiments, the calibration standard specifies any number of calibration points at which the EVSE is to be calibrated. In various embodiments, a calibration point specifies a voltage value, a current value, and/or any other electrical property that the EVSE is to provide and to be measured.

In at least one non-limiting example, the calibration standard specifies that calibration is to be performed at a first calibration point of 200 amps and 240 volts, and at a second calibration point of 10 amps and 240 volts. In another non-limiting example, the calibration standard specifies that calibration is to be performed at calibration points of 5%, 50%, and 95% of a maximum deliverable current and voltage of the EVSE.

In various embodiments, the calibration standard specifies any number of calibration ranges in which the EVSE is to be calibrated. In at least one non-limiting example, the calibration standard specifies a first calibration point is to be within 0% to 10% of a maximum output current and voltage of the EVSE, and a second calibration point is to be within 90% to 100% of the maximum output current and voltage of the EVSE.

In some embodiments, the calibration standard is determined based on user input selecting the calibration standard. In some embodiments, the calibration standard is automatically determined based on a geographic location of the EVSE or the intermediary calibration device. In some embodiments, the calibration standard is determined based on a make or model of the EVSE. After block 504, process 500 proceeds to decision block 506.

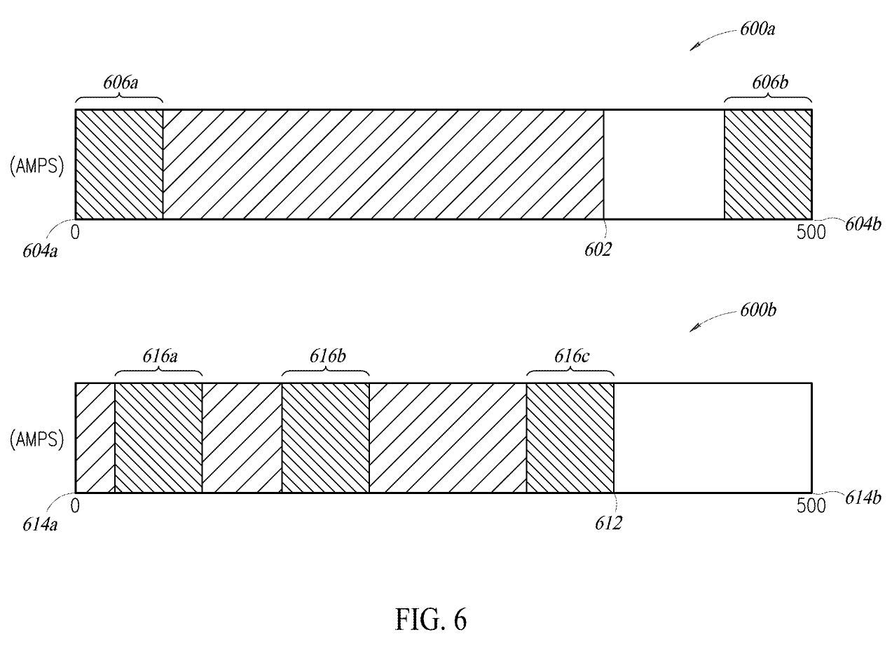

At decision block 506, a determination is made whether calibration points satisfying the calibration standard and usable based on the EVSE and battery characteristics are possible. If yes, process 500 continues to block 510. If no, process 500 continues to block 508. In some embodiments, it is determined that calibration points satisfying the calibration standard and usable based on the EVSE and battery characteristics are not possible when a calibration point specifies a current or voltage above a maximum charging current or voltage of the EV battery. Non-limiting examples of determining whether calibration points satisfy calibration standards and are usable based on the EVSE and battery characteristics are discussed with respect to FIG. 6.

At block 508, a user is notified that calibration cannot be performed, at least under present circumstances. In various embodiments, the notification is based on light, sound, vibration, etc. In some embodiments, the notification is text-based and is displayed using display 202 of intermediary calibration device 102 shown in FIG. 2. In some embodiments, the notification is provided to another device associated with the user or another entity associated via email, short message service (i.e., “SMS”), an application programming interface, etc.

In some embodiments, the notification indicates an amount that the charge capacity (or state of charge) of the EV is to be reduced to enable calibration at the calibration point, such as by driving the EV to a next EVSE to be calibrated or otherwise discharging the EV battery. After block 508, process 500 ends.

In some embodiments, the notification is provided before the intermediary calibration device is connected to the EVSE. In at least one non-limiting example, selection of the calibration standard through an interface of the intermediary calibration device causes the intermediary calibration device to determine whether calibration points that satisfy the calibration standard can be accommodated by the EV battery. This may, for example, assist the user in determining an order in which to drive the EV to various EVSEs for calibration, an amount to charge or discharge the EV battery in preparation for calibrating one or more EVSEs, etc.

At block 510, one or more candidate calibration points are obtained. In some embodiments, the one or more candidate calibration points are obtained based on user input provided to the intermediary calibration device. In at least one non-limiting example, when calibration is initiated, the intermediary calibration device provides an interface for inputting the one or more calibration points. In some embodiments, the intermediary calibration device provides an interface for selecting the one or more calibration points from a memory of the intermediary calibration device.

In various embodiments, the one or more candidate calibration points are obtained from a separate computing device such as a server. In some such embodiments, the intermediary calibration provides the separate computing device with at least one of the EVSE characteristics, the battery characteristics, or any combination thereof. In response, the intermediary calibration device receives the one or more candidate calibration points from the separate computing device.

In various embodiments, the intermediary calibration device automatically calculates the one or more candidate calibration points based on at least one of the EVSE characteristics, the battery characteristics, or any combination thereof. In some embodiments, a first candidate calibration point is determined based on a maximum charging current of the battery as determined based on the obtained battery characteristics. In some embodiments, the first candidate calibration point is be determined based on a flat offset or a percent offset from the maximum charging current. In some embodiments, the first candidate calibration point is 100%, 95%, 90%, etc. of the maximum charging current. In some embodiments, the first candidate calibration point is 1 amp, 5 amps, 10 amps, etc. less than the maximum charging current. In some embodiments, a second candidate calibration point is determined based on a minimum deliverable current of the EVSE, such as 100%, 105%, 110%, etc. of the minimum deliverable current, or 1, 2, 5, etc. amps above the minimum deliverable current. By automatically calculating a first candidate calibration point based on a maximum charging current of the battery and a second candidate calibration point based on the minimum deliverable current of the EVSE, a difference between the first candidate calibration point and the second candidate calibration point may be maximized.

In some embodiments where the one or more candidate calibration points are obtained from a computing device or are automatically calculated by the intermediary calibration device, process 500 proceeds from block 510 to block 516 because the candidate calibration points have already been determined to satisfy the calibration standard, and to be usable based on the EVSE and battery characteristics. After block 510, process 500 proceeds to decision block 512.

At decision block 512, a determination is made whether the one or more candidate calibration points satisfy the calibration standard. In some embodiments where the one or more candidate calibration points are manually configured or selected from memory, the one or more candidate calibration points may not satisfy the calibration standard. In at least one non-limiting example, a calibration point is outside of a calibration range defined by the calibration standard. To illustrate, if the calibration standard specifies that the EVSE is to be measured in a first calibration range of between 0% and 10% of its maximum deliverable current and a second calibration range between 90% and 100% of its maximum deliverable current, a candidate calibration point at 40% of the maximum deliverable current satisfies neither the first calibration range nor the second calibration range. Accordingly, the candidate calibration point does not satisfy the calibration standard. Continuing the example, when the candidate calibration point is at 5% of the maximum deliverable current, the candidate calibration point is within the first calibration range and therefore satisfies the calibration standard.

In various embodiments, a determination of whether any number of candidate calibration points collectively satisfy the calibration standard is made. Continuing the above example, when the candidate calibration points are at 5%, 40%, and 95% of the maximum deliverable current, the candidate calibration points may be determined not to satisfy the calibration standard because the candidate calibration point at 40% of the maximum deliverable current does not satisfy any calibration range of the calibration standard. In some embodiments wherein each calibration range of the calibration standard is satisfied but additional candidate calibration points are provided, the candidate calibration points are determined to satisfy the calibration standard.

At decision block 514, a determination is made whether the candidate calibration points are usable based on the EVSE and battery characteristics. If yes, process 500 continues to block 516. If no, process 500 continues to block 510 to obtain one or more new candidate calibration points. In at least one non-limiting example, when a candidate calibration point includes a current that is greater than can be accommodated by the battery, the candidate calibration point is determined not to be usable. In another non-limiting example, when the candidate calibration point includes a current that is greater than can be provided by the EVSE, the candidate calibration point is determined not to be usable.

In some cases, the battery characteristics impose limits on calibration points at which the EVSE can be calibrated using the battery as an electrical load.

A maximum charging current for a battery depends on the present charge capacity of the battery. In general, when the battery is at a low charge capacity, such as 0%-50%, the battery is capable of charging at a maximum current (e.g., the maximum current in the constant current or “CC” portion of Table 1). However, as charge capacity of the battery increases, the charging current typically decreases though the charging voltage is held steady until the battery is fully charged. When the battery is fully charged (or charged to a desired final charge), the charging current for the battery decreases to zero. Accordingly, as the state of charge of the battery approaches 100%, the battery cannot be further charged and therefore cannot serve as an electrical load for calibration of the EVSE.

Accordingly, the capacity of the EV battery to act as an electrical load for calibration of the EVSE may be limited when the state of charge of the battery is above a threshold such as 50%, 70%, 90%, etc. In some cases, the state of charge of the battery may be too high to enable calibration according to a calibration standard. In at least one non-limiting example, a calibration standard specifies that the EVSE is to be calibrated at a first calibration point less than 10% of a maximum deliverable power of the EVSE and at a second calibration point greater than 90% of a maximum deliverable power of the EVSE. When a charge capacity of the EV battery is above a threshold at which 90% of the maximum deliverable power of the EVSE can be absorbed, calibration at the second calibration point cannot be performed using the EV battery.

Similarly, when calibrating delivery of power from the battery to the EVSE (e.g., to in turn deliver power to the grid), the battery may not be capable of providing sufficient power at certain calibration points to perform the calibration. For example, when the state of charge of the battery is below a threshold such as 10%, 25%, or 50%, a capability of the battery to provide power to the EVSE may be limited, and negotiation of the calibration points may be required.

As shown in FIG. 5, in various embodiments process 500 proceeds from decision block 512 or decision block 514 to block 510 to obtain one or more new candidate calibration points. In some such embodiments, decision block 510 obtains the one or more new candidate calibration points based on the determination made at decision block 512 or decision block 514. In at least one non-limiting example, when a candidate calibration point is determined not to be usable at block 514 because a current, voltage, etc. of the candidate calibration point is too high for the battery to accommodate, block 510 determines the one or more new calibration points such that the battery can accommodate the one or more new calibration points.

In various embodiments where a new candidate calibration point is to be obtained, the intermediary calibration device indicates to a user a reason that a candidate calibration point could not be used. In some embodiments, in response to determining that a candidate calibration point does not satisfy the calibration standard at block 512, the intermediary calibration device notifies the user that a calibration point does not satisfy the calibration standard. In some such embodiments, the intermediary calibration device provides information regarding the calibration standard, such as one or more ranges in which calibration is to be performed according to the calibration standard. In some embodiments, the intermediary calibration device provides a recommended calibration point. In some embodiments, the intermediary calibration device provides instructions for manually selecting a new candidate calibration point that satisfies the calibration standard. In various embodiments, in response to determining that the candidate calibration points are not usable at decision block 514, actions similar to those discussed with respect to decision block 512 are taken.

At block 516, one or more calibration points are determined based on the one or more candidate calibration points. In some embodiments, the one or more candidate calibration points are used as the calibration points. In some embodiments where the one or more candidate points satisfy the calibration standard but include one or more additional calibration points that do not satisfy the calibration standard, the one or more candidate calibration points that satisfy the calibration standard are selected as the one or more calibration points. After block 516, process 500 ends.

FIG. 6 illustrates examples of scenarios in which a calibration standard can or cannot be accommodated by an EV battery. As discussed herein, the present state of charge of an EV battery affects a maximum current at which the EV battery can be charged. Because the EV battery is used as an electrical load for calibration, the maximum current at which the EV battery can be charged is typically the maximum current at which calibration can be performed.

Graph 600a illustrates an example of a calibration standard that cannot be satisfied using an EV battery as the electrical load for calibration. Graph 600a shows current in amps from 0A to 500A. The EV battery maximum charging current (i.e., “max charging current”) 602 indicates a present maximum charging current that the EV battery can receive. The EVSE minimum current 604a is a minimum current that can be supplied by the EVSE, and EVSE maximum current 604b is a maximum current that can be supplied by the EVSE. A calibration standard specifies a first calibration range 606a and a second calibration range 606b in which the EVSE is to be calibrated. In the example shown in graph 600a, the calibration standard specifies that a first calibration is to be performed at no more than 10% of the maximum current output of the EVSE (i.e., within first calibration range 606a) and a second calibration to be performed at no less than 90% of the maximum current output of the EVSE (i.e., within second calibration range 606b). Thus, to satisfy the calibration standard, the calibration is to be performed using the intermediary calibration device within the first calibration range 606a and the second calibration range 606b. But the maximum charging current 602 that the EV battery can receive is not high enough for the EV battery to be used as an electrical load for calibration in second calibration range 606b. Therefore, calibration according to the calibration standard cannot be performed at the present condition (e.g., state of charge) of the EV battery.

Graph 600b illustrates an example of a calibration standard that can be satisfied using an EV battery as the electrical load for calibration. Graph 600b shows current in amps from 0A to 500A. The EV battery maximum charging current (i.e., “max charging current”) 612 indicates a present maximum charging current that the EV battery can receive. The EVSE minimum current 614a is a minimum current that can be supplied by the EVSE, and EVSE maximum current 614b is a maximum current that can be supplied by the EVSE.

In this example, the calibration standard specifies three calibration ranges, namely a first calibration range 616a, a second calibration range 616b, and a third calibration range 616c. In the example shown in graph 600b, the calibration standard specifies that calibration is to be performed at (1) no more than 10% maximum current output of the EVSE (i.e., within the first calibration range 616a); (2) between 30% and 40% of the maximum current output of the EVSE (i.e., within the second calibration range 616b); and (3) between 60% and 70% maximum current output of the EVSE (i.e., within the third calibration range 616c). To satisfy the calibration standard, calibration is to be performed using the intermediary calibration device within each of the three calibration ranges. Because the EV battery’s maximum charging current 612 exceeds a minimum current of each of the three calibration ranges, calibration according to the calibration standard can be performed.

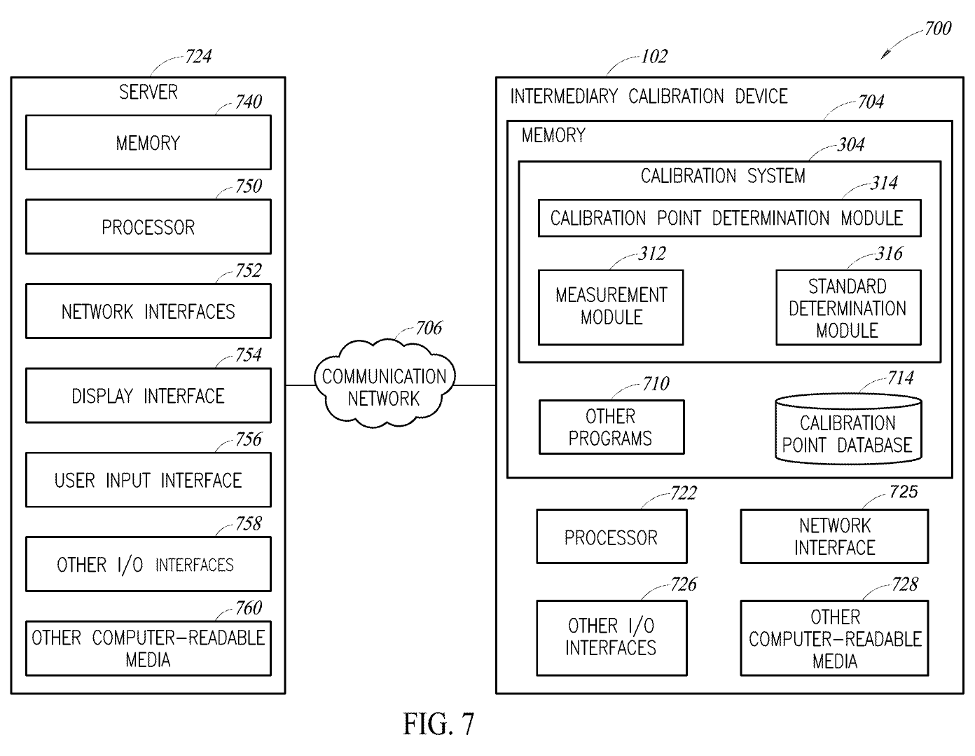

FIG. 7 is a system diagram that describes at least one implementation of a computing system 700 for implementing embodiments described herein. System 700 includes intermediary calibration device 102 and a server 724.

As described herein, the intermediary calibration device 102 is configured to perform functionality for calibrating a power source using an EV battery as an electrical load. In this example, one or more general purpose or special purpose computing devices or components may be used to implement the intermediary calibration device 102. Accordingly, various embodiments described herein may be implemented in software, hardware, firmware, or in some combination thereof. Intermediary calibration device 102 includes, for example, memory 704, one or more processors 722, network interface 724, other input/output (I/O) interfaces 726, and other computer-readable media 728.

Processor 722 includes one or more processors, processing units, programmable logic, circuitry, or other computing components that are configured to perform embodiments described herein or to execute computer instructions to perform embodiments described herein. In some embodiments, processor 722 may include a single processor that operates individually to perform actions. In other embodiments, processor 722 may include a plurality of processors that operate to collectively perform actions, such that one or more processors may operate to perform some, but not all, of such actions.

Memory 704 includes one or more types of non-volatile or volatile storage technologies. Examples of memory 704 include, but are not limited to, flash memory, hard disk drives, optical drives, solid-state drives, various types of random-access memory (“RAM”), various types of read-only memory (“ROM”), other computer-readable storage media (also referred to as processor-readable storage media), other memory technologies, or any combination thereof. In some embodiments, memory 704 stores data, including computer-executable instructions that are utilized by processor 722 to perform actions, including at least some embodiments described herein.

In some embodiments, memory 704 stores calibration system 304. Calibration system 304 includes calibration point determination module 314, measurement module 312, and standard determination module 316, configured to perform actions as described at least with respect to FIG. 3.

In some embodiments, memory 704 stores other programs 710, such as operating systems, user applications, or other computer programs. In some embodiments, memory 704 stores calibration point database 714, which includes one or more calibration points for various calibration standards.

Network interfaces 725 are configured to communicate with other computing devices, such as server 724, EV 106, or EVSE 104, via communication network 706. Network interfaces 725 include transmitters and receivers (wired and/or wireless, not illustrated) configured to send and receive data, requests, and instructions.

In some embodiments, other I/O interfaces 726 include interfaces for various other input or output devices, such as audio interfaces, other video interfaces, USB interfaces, physical buttons, keyboards, haptic interfaces, tactile interfaces, or the like. Other computer-readable media 728 may include other types of stationary or removable computer-readable media, such as removable flash drives, external hard drives, or the like.

Memory 740, processor 750, network interfaces 752, display interface 754, user input interface 756, other I/O interfaces 758, and other computer-readable media 760 of server 724 are in various embodiments similar to corresponding components discussed with respect to intermediary calibration device 102.

In some embodiments, memory 740 stores one or more calibration points associated with an entity, geographic location, type of EVSE, etc. In some embodiments, intermediary calibration device 102 requests server 724 to provide one or more calibration points based on one or more characteristics of an EVSE to be calibrated, one or more characteristics of an EV battery to be used as an electrical load in calibrating the EVSE, or any combination thereof.

The following examples summarize aspects of the embodiments described above.

In various embodiments, an apparatus includes: a sensor configured to measure an electrical output supplied by a power source to a battery; one or more processors; and one or more memories collectively storing instructions executable by the one or more processors to cause the one or more processors to: determine a first target electrical output that the power source can supply to the battery and that the battery can receive; request the power source to supply the first target electrical output to the battery; measure, using the sensor, a first value of the electrical output supplied by the power source to the battery; and calibrate the power source using at least the measured first value of electrical output and a first electrical output reported by the power source.

In some embodiments the one or more processors determine the first target electrical output by being further configured to: obtain a charging request from a battery management system associated with the battery; and determine the first target electrical output based on the charging request.

In some embodiments, the one or more processors determine the first target electrical output based on user input that specifies the first target electrical output.

In some embodiments, the one or more processors are further configured to: determine a calibration standard for calibrating the power source; and determine the first target electrical output based on the calibration standard.

In some embodiments, the one or more processors determine the calibration standard based on a geographic location of the power source.

In some embodiments, the one or more processors are further configured to: determine a second target electrical output that the power source can supply to the battery and that the battery can receive, wherein the second target electrical output is different than the first target electrical output; request the power source to supply the second target electrical output to the battery; measure, using the sensor, a second value of the electrical output supplied by the power source to the battery; and perform a multi-point calibration of the power source using at least the measured first value of electrical output, the first electrical output reported by the power source, the measured second value of electrical output, and a second electrical output reported by the power source.

In some embodiments, the one or more processors are further configured to: determine the first target electrical output and the second target electrical output such that a difference between the first target electrical output and the second target electrical output exceeds a difference threshold.

In some embodiments, the one or more processors are further configured to: obtain a minimum electrical output that the power source can supply to the battery; and determine the second target electrical output based on the minimum electrical output of the power source.

In various embodiments, a system includes: a sensor configured to measure an electrical output supplied by a power source to a load; and processing circuitry configured to: determine a calibration point at which the power source is to be calibrated; determine a capability of the power source to supply energy to the load at a power level based on the calibration point; receive a power request to provide power to the load at the power level; request the power source to supply an electrical output in accordance with the charge request; measure, using the sensor, a value of the electrical output supplied by the power source to the load; and calibrate the power source using at least the measured value of electrical output supplied by the power source and an electrical output reported by the power source.

In some embodiments, the processing circuitry is configured to: determine a maximum electrical output that the load can presently receive; and determine the calibration point based on the maximum electrical output.

In some embodiments, the processing circuitry is configured to: determine, based on the capability of the power source, a minimum deliverable electrical output of the power source; and determine the calibration point based on the minimum deliverable electrical output.

In some embodiments, the processing circuitry is configured to: determine the calibration point from communication with a separate computing device.

In some embodiments, the processing circuitry is configured to: determine the calibration point based on user input.

In some embodiments, the processing circuitry is configured to: represent to a load management system of the load that a power level indicated by the calibration point is a maximum power level that the power source can supply.

In some embodiments, the processing circuitry is configured to: determine, based on a present characteristic of the load, that calibration at the calibration point cannot be performed; and automatically determine, based on the present characteristic of the load, a new calibration point at which calibration can be performed.

In some embodiments, the processing circuitry is configured to: determine a power level indicated by the calibration point; and determine that the load cannot accept power at the power level indicated by the calibration point based on the present characteristic of the load.

In some embodiments, the load is an electric vehicle (EV) battery and the power source is an electric vehicle supply equipment (EVSE).

In some embodiments, a method includes: determining a plurality of calibration points at which to calibrate a battery management system (BMS) of a battery according to a calibration standard; requesting the battery to provide power to a load according to the plurality of calibration points; measuring, for each of the plurality of calibration points, a corresponding power supplied by the battery to the load; and calibrating the BMS using at least the measured corresponding powers and values of supplied power reported by the BMS.

In some embodiments, the method includes: determining that the battery cannot provide power for at least one calibration point of the plurality of calibration points; and notifying a user that calibration at the at least one calibration point cannot be performed.

In some embodiments, determining the plurality of calibration points includes: determining a first calibration point of the plurality of calibration points based on a present state of charge of the battery; and determining a second calibration point of the plurality of calibration points based on a minimum deliverable power of the battery.

In some embodiments, the method includes: connecting an intermediary calibration device between the BMS and the load, wherein the intermediary calibration device is configured to communicate with the BMS and a load management system of the load, using the intermediary calibration device to communicate with the BMS to determine whether the battery can provide power for calibrating the BMS at the plurality of calibration points, and using the intermediary calibration device to communicate with the BMS to request the battery to provide power to the load according to the plurality of calibration points.

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

1. An apparatus comprising:
a sensor configured to measure an electrical output supplied by a power source to a battery;
one or more processors; and
one or more memories collectively storing instructions executable by the one or more processors to cause the one or more processors to:
determine a first target electrical output that the power source can supply to the battery and that the battery can receive;
request the power source to supply the first target electrical output to the battery;
measure, using the sensor, a first value of the electrical output supplied by the power source to the battery; and
calibrate the power source using at least the measured first value of electrical output and a first electrical output reported by the power source.

2. The apparatus of claim 1, wherein the one or more processors determine the first target electrical output by being further configured to:
obtain a charging request from a battery management system associated with the battery; and
determine the first target electrical output based on the charging request.

3. The apparatus of claim 1, wherein the one or more processors determine the first target electrical output based on user input that specifies the first target electrical output.

4. The apparatus of claim 1, wherein the one or more processors are further configured to:
determine a calibration standard for calibrating the power source; and
determine the first target electrical output based on the calibration standard.

5. The apparatus of claim 4, wherein the one or more processors determine the calibration standard based on a geographic location of the power source.

6. The apparatus of claim 1, wherein the one or more processors are further configured to:
determine a second target electrical output that the power source can supply to the battery and that the battery can receive, wherein the second target electrical output is different than the first target electrical output;
request the power source to supply the second target electrical output to the battery;
measure, using the sensor, a second value of the electrical output supplied by the power source to the battery; and
perform a multi-point calibration of the power source using at least the measured first value of electrical output, the first electrical output reported by the power source, the measured second value of electrical output, and a second electrical output reported by the power source.

7. The apparatus of claim 6, wherein the one or more processors are further configured to:
determine the first target electrical output and the second target electrical output such that a difference between the first target electrical output and the second target electrical output exceeds a difference threshold.

8. The apparatus of claim 6, wherein the one or more processors are further configured to:
obtain a minimum electrical output that the power source can supply to the battery; and
determine the second target electrical output based on the minimum electrical output of the power source.

9. A system comprising:
a sensor configured to measure an electrical output supplied by a power source to a load; and
processing circuitry configured to:
determine a calibration point at which the power source is to be calibrated;
determine a capability of the power source to supply power to the load at a power level based on the calibration point;
receive a power request to provide power to the load at the power level;
request the power source to supply an electrical output in accordance with the power request;
measure, using the sensor, a value of the electrical output supplied by the power source to the load; and
calibrate the power source using at least the measured value of electrical output supplied by the power source and an electrical output reported by the power source.

10. The system of claim 9, wherein the processing circuitry is configured to:
determine a maximum electrical output that the load can presently receive; and
determine the calibration point based on the maximum electrical output.

11. The system of claim 9, wherein the processing circuitry is configured to:
determine, based on the capability of the power source, a minimum deliverable electrical output of the power source; and
determine the calibration point based on the minimum deliverable electrical output.

12. The system of claim 9, wherein the processing circuitry is configured to:
determine the calibration point from communication with a separate computing device.

13. The system of claim 9, wherein the processing circuitry is configured to:
determine the calibration point based on user input.

14. The system of claim 9, wherein the processing circuitry is configured to:
represent to a load management system of the load that a power level indicated by the calibration point is a maximum power level that the power source can supply.

15. The system of claim 9, wherein the processing circuitry is configured to:
determine, based on a present characteristic of the load, that calibration at the calibration point cannot be performed; and
automatically determine, based on the present characteristic of the load, a new calibration point at which calibration can be performed.

16. The system of claim 15, wherein the processing circuitry is configured to:
determine a power level indicated by the calibration point; and
determine that the load cannot accept power at the power level indicated by the calibration point based on the present characteristic of the load.

17. The system of claim 9, wherein the load is an electric vehicle (EV) battery and the power source is an electric vehicle supply equipment (EVSE).

18. A method comprising:
determining a plurality of calibration points at which to calibrate a battery management system (BMS) of a battery according to a calibration standard;
requesting the battery to provide power to a load according to the plurality of calibration points;
measuring, for each of the plurality of calibration points, a corresponding power supplied by the battery to the load; and
calibrating the BMS using at least the measured corresponding powers and values of supplied power reported by the BMS.

19. The method of claim 18, further comprising:
determining that the battery cannot provide power for at least one calibration point of the plurality of calibration points; and
notifying a user that calibration at the at least one calibration point cannot be performed.

20. The method of claim 18, wherein determining the plurality of calibration points includes:
determining a first calibration point of the plurality of calibration points based on a present state of charge of the battery; and
determining a second calibration point of the plurality of calibration points based on a minimum deliverable power of the battery.

21. The method of claim 18, further comprising:
connecting an intermediary calibration device between the BMS and the load, wherein the intermediary calibration device is configured to communicate with the BMS and a load management system of the load,
using the intermediary calibration device to communicate with the BMS to determine whether the battery can provide power for calibrating the BMS at the plurality of calibration points, and
using the intermediary calibration device to communicate with the BMS to request the battery to provide power to the load according to the plurality of calibration points.
